(19) United States
(12) Patent Application Publication
(10) Pub. No.: US 2013/0193418 A1
(43) Pub. Date: Aug. 1, 2013

(54) LIGHT-EMITTING APPARATUS, IMAGE-FORMING APPARATUS, DISPLAY APPARATUS, AND IMAGE PICKUP APPARATUS

(71) Applicant: CANON KABUSHIKI KAISHA, Tokyo (JP)

(72) Inventor: Nobuyuki Ishikawa, Sanbu-gun (JP)

(73) Assignee: CANON KABUSHIKI KAISHA, Tokyo (JP)

(21) Appl. No.: 13/752,084

(22) Filed: Jan. 28, 2013

(30) Foreign Application Priority Data
Jan. 31, 2012 (JP) 2012-018815

(51) Int. Cl. H01L 51/52; H01L 51/56; H01L 33/08

(52) U.S. Cl. CPC H01L 51/5203; H01L 33/08; H01L 51/56
USPC 257/40; 257/88; 438/34

(57) ABSTRACT

An organic EL element uses the maximum optical interference effect and satisfactorily emits light. The first optical distance L₁ between the light-emitting layer and the first electrode of the organic EL element satisfies the following requirements: L₁>0 and (λ/8)×(−1−2Φ₁/π)<L₁<(λ/8)×(1−2Φ₁/π), wherein λ represents the maximum peak wavelength of the spectrum of light emitted by the organic EL element, and Φ₁ represents the phase shift of the reflecting surface of the first electrode at the wavelength λ. The hole transport layer of the organic EL element is formed by coating.

### BACKGROUND OF THE INVENTION

1. Field of the Invention

The present invention relates to a light-emitting apparatus, an image-forming apparatus, a display apparatus, and an image pickup apparatus including organic electroluminescent (EL) elements.

2. Description of the Related Art

Recently, a demand for a reduction in power consumption of a display apparatus including organic EL elements has increased, and an improvement in emission efficiency of the organic EL element is required. A method of increasing the emission efficiency through an optical interference effect is known (International Publication No. WO01/039554).

Specifically, the optical distance L between a reflective electrode and a light emission position of an organic EL element is determined by Expression 1:

L=(2m−(Φ/π))×(λ/4)

wherein λ denotes a wavelength desired to be enhanced, Φ denotes the sum of phase shifts when light is reflected by the reflective electrode, and m denotes an integer of larger than 0. It is known that the optical interference effect becomes the maximum when m is 0. Incidentally, the organic compound layer of an organic EL element can be formed by, for example, vapor deposition or coating.

If the optical distance of an organic EL element is set to that when m is 0 in Expression 1, however, vapor deposition under reduced pressure usually used causes the following problems: In a known vapor deposition process, the evaporated molecules of an organic compound have a long mean free path length and high rectilinearity, which prevents the organic compound from adhering to the side surfaces of an electrode as illustrated in FIG. 5. As shown in FIG. 5, in usual vapor deposition, organic compound layers 21a and 22b are respectively formed on an electrode 21 and a substrate 10. However, the side surfaces of the electrode 21 are shadowed by the organic compound layer 22a adhering onto the ends of the electrode 21, and thereby the organic compound is prevented from adhering to the side surfaces. Furthermore, in an organic EL element satisfying the condition of m=0, the thickness of the organic compound layer is small, which makes the problem significant. If another electrode pairing with the electrode 21 is formed under conditions in which the side surfaces of the electrode 21 are not covered with the organic compound, a short circuit occurs at the portion to cause a problem that the organic EL element does not emit light.

A countermeasure to this problem is, for example, a method of covering the ends of the electrode 21 with an insulating layer. This method, however, increases the number of steps of the production process and has a risk of remaining dust generated in patterning of the insulating layer on the electrode 21. In addition, as in described above, since the organic compound does not adhere to the side surfaces and the bottom surface of the dust, a short circuit occurs between the electrode 21 and the electrode pairing with it.

### SUMMARY OF THE INVENTION

An embodiment of the present invention provides an organic EL element having an optical distance set to that satisfying Expression 1 in which m is 0 and favorably emitting light.

An aspect of the present invention relates to a light-emitting apparatus including:

a substrate; and

a plurality of organic EL elements on the substrate, the organic EL elements each including a first electrode, a second electrode, a light-emitting layer, and a charge transport layer between the first electrode and the light-emitting layer, the first electrode being disposed for each organic EL element, and light emitted from the light-emitting layer being extracted from the second electrode, wherein

the charge transport layer is formed by coating; and

the first optical distance L₁ between the light emission position of the light-emitting layer and the reflecting surface of the first electrode of each organic EL element satisfies Expression A:

(λ/8)×(−1−2Φ₁/π)<L₁<(λ/8)×(1−2Φ₂/π), and L₁>0

wherein, λ represents the maximum peak wavelength of the spectrum of light emitted by each organic EL element, and Φ₁ represents the phase shift of the reflecting surface of the first electrode at the wavelength λ.

Another aspect of the present invention relates to a method of producing a light-emitting apparatus including a substrate and a plurality of organic EL elements on the substrate, the organic EL elements each including a first electrode, a second electrode, a light-emitting layer, and a charge transport layer between the first electrode and the light-emitting layer, the first electrode being disposed for each organic EL element, and light emitted from the light-emitting layer being extracted from the second electrode, the method including:

forming a first electrode on a substrate;

forming a charge transport layer on the first electrode by coating;

forming a light-emitting layer on the charge transport layer; and

forming a second electrode on the light-emitting layer, wherein

the first optical distance L₁ between the light emission position of the light-emitting layer and the reflecting surface of the first electrode of each organic EL element satisfies Expression J:

(λ/8)×(−1−2Φ₁/π)<L₁<(λ/8)×(1−2Φ₁/π), and L₁>0

wherein, λ represents the maximum peak wavelength of the spectrum of light emitted by each organic EL element, and Φ₁ represents the phase shift of the reflecting surface of the first electrode at the wavelength λ.

According to an embodiment of the present invention, an organic EL element having an optical distance set to that satisfying Expression 1 in which m is 0 and also favorably emitting light is provided.

Further features of the present invention will become apparent from the following description of exemplary embodiments with reference to the attached drawings.

### BRIEF DESCRIPTION OF THE DRAWINGS

FIG. 1A is a perspective schematic diagram illustrating an example of a light-emitting apparatus of the present invention.

FIG. 1B is a partial cross-sectional schematic diagram illustrating the example of the light-emitting apparatus.

FIGS. 2A and 2B are enlarged schematic views of the vicinities of the first electrode of a light-emitting apparatus of an embodiment of the present invention.

FIG. 3 is a graph showing refractive indices of a film formed by coating and a film formed by vapor deposition.

FIGS. 4A to 4D are cross-sectional schematic diagrams showing an example of a process of producing a light-emitting apparatus of an embodiment of the present invention.

FIG. 5 is an enlarged schematic view of the vicinity of an electrode on a substrate of a known light-emitting apparatus.

### DESCRIPTION OF THE EMBODIMENTS

Embodiments of the present invention will now be described with reference to the drawings, but the present invention is not limited thereto. Note that well-known or publicly known technologies in the art are applied to portions that are not specifically illustrated or described in the specification.

### Light-Emitting Apparatus

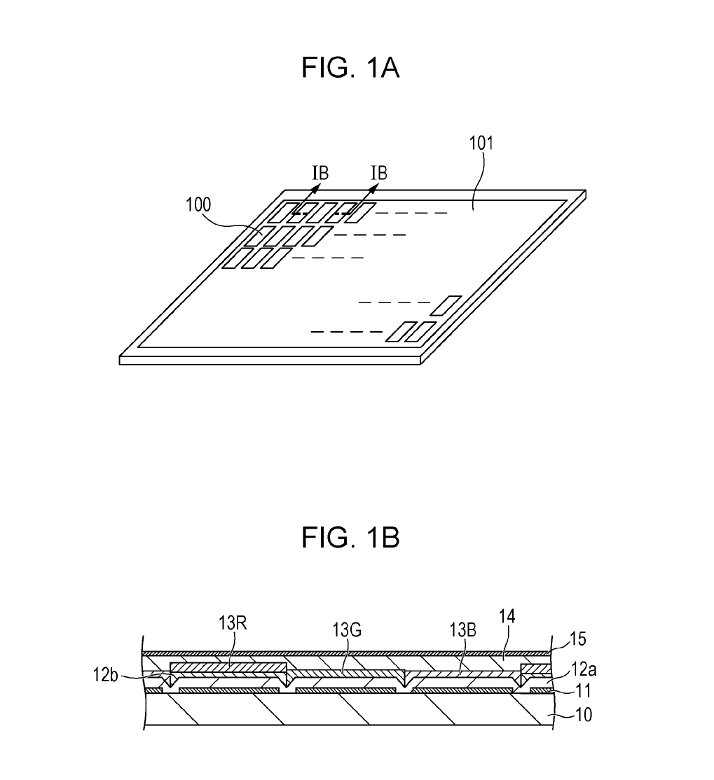

FIG. 1A is a perspective schematic diagram illustrating a light-emitting apparatus according to an embodiment of the present invention. The light-emitting apparatus of an embodiment of the present invention includes a plurality of pixels 100 each having an organic EL element. The pixels 100 are arrayed in a matrix form to form a display region 101. The pixel is a region corresponding to the light-emitting region of one light-emitting element. In the light-emitting apparatus of an embodiment of the present invention, the light-emitting element is the organic EL element, and the organic EL element emitting light of one color is disposed in each pixel 100. Examples of the color of emission light of the organic EL element include red, green, and blue and also include white, yellow, and cyan. In the light-emitting apparatus of an embodiment of the present invention, a plurality of pixel units each composed of a plurality of pixels that emit light of different colors (e.g., a pixel emitting red light, a pixel emitting green light, and a pixel emitting blue light) are arrayed. Herein, the pixel unit indicates a minimum unit that can emit light of a desired color by mixing light emitted by each pixel. Alternatively, the light-emitting apparatus of an embodiment of the present invention may have a structure in which a plurality of pixels emitting light of the same color are aligned in one-dimensional direction for, for example, a printer head.

FIG. 1B is a partial cross-sectional schematic view taken along the line IB-IB in FIG. 1A. One pixel 100 on a substrate 10 includes an organic EL element. The organic EL element includes a first electrode (anode) 11, a hole transport layer 12a, 12b, a light-emitting layer 13R, 13G, 13B, an electron transport layer 14, and a second electrode (cathode) 15. The organic EL element of an embodiment of the present invention has a structure in which the first electrode 11 has a reflecting surface for reflecting light emitted toward the first electrode 11 from the light-emitting layer, and the light is extracted from the second electrode 15. The light-emitting layer 13R emits red light, the light-emitting layer 13G emits green light, and the light-emitting layer 13B emits blue light. The light-emitting layers 13R, 13G, and 13B are patterned so as to correspond to the pixels (organic EL elements) emitting red, green, and blue light, respectively. The first electrode 11 is formed for each pixel (organic EL element), and each first electrode 11 is isolated from other first electrodes 11 of adjacent pixels (organic EL elements). The electron transport layer 14 and the second electrode 15 may be formed so as to be common for adjacent pixels or may be patterned for each pixel. The organic EL element is sealed with sealing glass (not shown) for preventing penetration of moisture and oxygen.

In order to utilize the optical interference effect, the organic EL element of an embodiment of the present invention is designed such that the first optical distance L₁ between the light emission position of the light-emitting layer 13R, 13G, 13B and the reflecting surface of the first electrode 11 satisfies Expression 2:

L₁=−(Φ₁/π)×(λ/4)

wherein, λ represents the maximum peak wavelength of the spectrum of light emitted by each organic EL element, and Φ₁ represents the phase shift of the first electrode 11 at the wavelength 2, wherein the maximum peak wavelength is the wavelength of light emitted by each organic EL element with the greatest optical amplitude.

When the optical constants of two materials constituting a reflecting surface, i.e., the material through which light travels and the material into which the light enters, are (n₁,k₁) and (n₂,k₂), respectively, the phase shift (4) at the reflecting surface is expressed by Expression 3:

φ=tan⁻¹(2n₁k₂/(n₁²−n₂²−k₂²)).

That is, the phase shift Φ₁ is a negative value. Incidentally, these optical constants can be measured with, for example, a spectroscopic ellipsometer.

It is possible to satisfy Expression 2 by, for example, controlling the thickness of the hole transport layer 12a or forming a hole transport layer 12b in a part of the organic EL elements.

Even if Expression 2 is not satisfied due to an error occurred during the formation of the organic compound layer or the influence of emission distribution in the light-emitting layer, the wavelength λ is enhanced as long as the shift of the first optical distance L₁ from the range satisfying Expression 2 is within a range of ±λ/8. That is, the organic EL element of an embodiment of the present invention may be designed so as to satisfy Expression 4:

(λ/8)×(−1−2Φ₁/π)<L₁<(λ/8)×(1−2Φ₁/π), and L₁>0.

In particular, the shift of the first optical distance L₁ from the range satisfying Expression 2 can be controlled within a range of ±λ/16. That is, the organic EL element of an embodiment of the present invention may be produced so as to satisfy Expression 5:

(λ/16)×(−1−4Φ₁/π)≦L₁≦(λ/16)×(1−4Φ₁/π), and L₁>0.

The phase shift of the first electrode 11 having a metal layer is approximately −π. Accordingly, on the basis of Expressions 4 and 5, the organic EL element may be designed such that the first optical distance L₁ satisfies Expressions 4′:

λ/8<L₁<3λ/8, or

3λ/16≦L₁≦5λ/16. Expression 5′:

In addition, the optical interference effect is enhanced by controlling the second optical distance L₂ between the light emission position of the light-emitting layer 13R, 13G, 13B and the reflecting surface of the second electrode 15 satisfies Expression 6:

L₂=−(Φ₂/π)×(λ/4)

wherein, Φ₂ represents the phase shift of the second electrode 15 at the wavelength λ.

As described above, even if Expression 6 is not satisfied due to an error occurred during formation of the organic compound layer or the influence of emission distribution in the light-emitting layer, the wavelength λ is enhanced as long as the shift of the second optical distance L₂ from the range satisfying Expression 6 is within a range of ±λ/8. In particular, the shift of the second optical distance L₂ from the range satisfying Expression 6 can be controlled within a range of ±λ/16. That is, the organic EL element of an embodiment of the present invention may be produced so as to satisfy Expression 7:

(λ/8)×(−1−2Φ₂/π)<L₂<(λ/8)×(1−2Φ₂/π), and L₂>0, or

(λ/16)×(−1−4Φ₂/π)≦L₂≦(λ/16)×(1−4Φ₂/π), and L₂>0. Expression 8:

The phase shift of the second electrode 15 having a metal layer is approximately −π. Accordingly, on the basis of Expressions 7 and 8, the second optical distance L₂ may satisfy Expressions 7′:

λ/8<L₂<3λ/8, or

3λ/16≦L₂≦5λ/16. Expression 8′:

The hole transport layer 12a in FIG. 1B corresponds to the charge transport layer of an embodiment of the present invention, and the hole transport layer 12b is formed so as to spread over a plurality of the first electrodes 11 and the substrate 10. In the embodiment of present invention, the substrate 10 is a structure formed prior to the formation of the first electrodes 11, and examples thereof include a glass substrate provided with thin-film transistors covered with an insulating layer thereon. The hole transport layer 12a is formed so as to spread over and be in contact with the first electrodes 11 and the substrate 10. That is, an embodiment of the present invention has a configuration not having any insulating layer covering the ends of the first electrodes 11 and does not have a configuration having the hole transport layer 12a on an insulating layer disposed so as to cover the ends of the first electrode 11. The embodiment of present invention, however, includes a configuration having a rib-like structure formed between two first electrodes 11 without covering the ends of the electrodes.

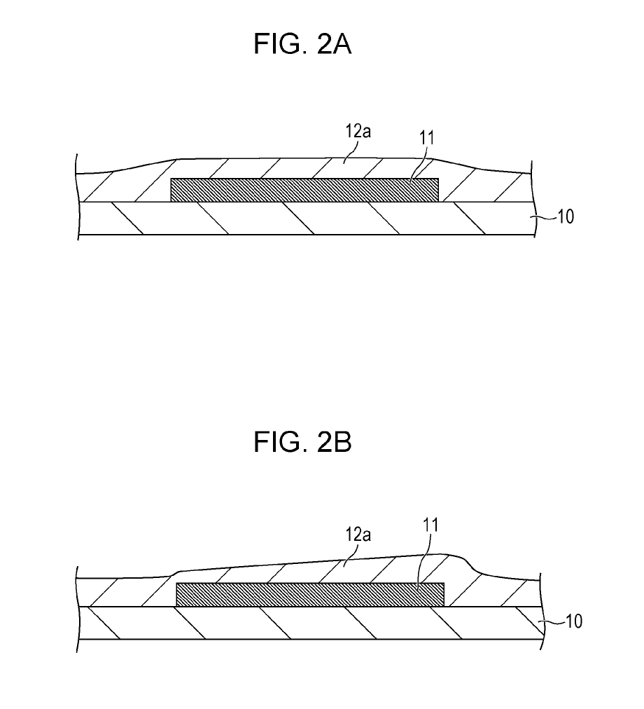

The hole transport layer 12a of an embodiment of the present invention is formed by coating such as slit coating or spin coating. FIG. 2A is an enlarged schematic view of a hole transport layer 12a formed on a first electrode 11 by slit coating. As shown in FIG. 2A, the hole transport layer 12a formed by coating is in contact with the top surface and the side surfaces of the first electrode 11 so as to cover also the side surfaces of the first electrode 11 and is formed smoothly from the top surface of the first electrode 11 to the substrate 10. This is because a solution containing the material for the hole transport layer 12a can cover also the side surfaces of the first electrode 11 without a break at the stepped portion between the first electrode 11 and the substrate 10 due to the effect of the surface tension of the solution containing the material for the hole transport layer 12a. The hole transport layer 12a covering also the side surfaces of the first electrodes 11 is formed by removing the solvent of the solution by evaporation. As a result, the organic EL element is prevented from a short circuit between the first electrode 11 and the second electrode 15 and can emit light.

FIG. 2B is an enlarged schematic view of a hole transport layer 12a and a first electrode 11 formed by another coating method, spin coating. The hole transport layer 12a formed by spin coating can also cover the side surfaces of the first electrode 11. As shown in FIG. 2B, however, spin coating causes a difference in the meniscus shapes at the ends of the first electrode 11 between the rotation center (the center of the substrate 10) side and the opposite side thereof, resulting in a large variation in thickness of the hole transport layer 12a on the first electrode 11.

In contrast, slit coating does not need rotation of the substrate, and as shown in FIG. 2A, the variation in thickness of the hole transport layer 12a on the first electrode 11 is small.

The organic EL element in an embodiment of the present invention utilizes the optical interference effect, in particular, a maximum optical interference effect and therefor has a small thickness for satisfying Expression 2 or any of Expression 4 to 8′. A large variation in thickness highly affects the light emission characteristics. Accordingly, the hole transport layer 12a may be formed by slit coating.

The hole transport layer 12a formed by coating as in an embodiment of the present invention has a lower refractive index than that of a film formed by vapor deposition using the same material. This is believed to be caused by that the volatile solvent reduces the film density (molecular density) of the hole transport layer 12a.

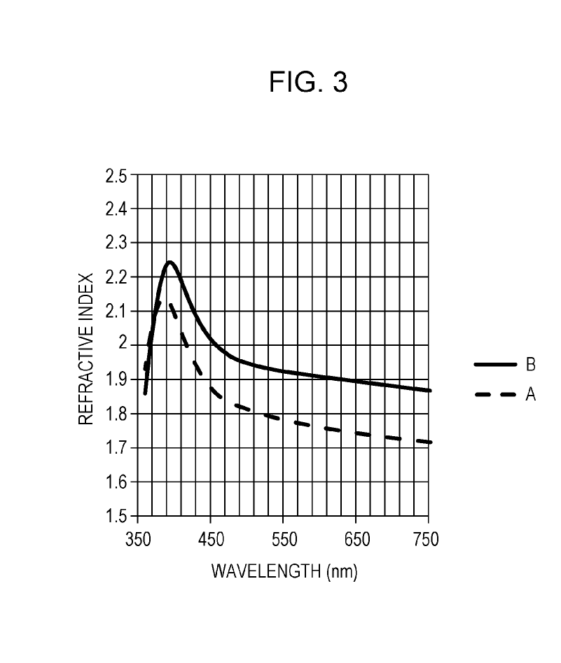

The difference in refractive index caused by a difference in the process of film formation will be described using Compound 1, which can be used as a hole-transporting material, as an example. FIG. 3 shows refractive indices of films formed by coating (slit coating) and vapor deposition on the same silicon substrate. In FIG. 3, the symbol A denotes the coating film, and the symbol B denotes the deposition film.

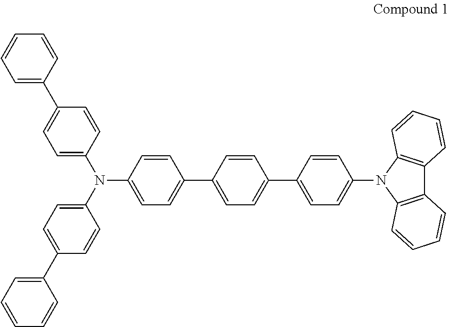 [SMILES: c1ccc(-c2ccc(N(c3ccc(-c4ccccc4)cc3)c3ccc(-c4ccc(-c5ccc(-n6c7ccccc7c7ccccc76)cc5)cc4)cc3)cc2)cc1]

The slit coating was performed using a toluene solution containing 0.5 wt % of Compound 1 under conditions of a slit interval of 50 μm, a distance between the slit head and the substrate of 50 μm, and a head movement speed of 60 mm/s. After coating, the substrate was heated at 80° C. for 10 minutes in a vacuum oven to anneal the coating film to give a thin film having a thickness of 18 nm. In vapor deposition, a thin film having a thickness of 18 nm was formed using Compound 1 under conditions of a pressure of 1.0×10⁻⁴ Pa and a film formation speed of 1.00 Å/s. The refractive indices of the resulting coating film (A) and deposition film (B) were measured by ellipsometry for comparison.

As obvious from FIG. 3, the coating film (A) shows smaller refractive indices than the deposition film (B) over the visible wavelength region of 400 nm or more and 750 nm or less.

The use of such a hole transport layer 12a having a small refractive index can reduce the loss due to surface plasmon (SP) on the surface of the first electrode 11 to increase the light emission efficiency. The SP loss is a phenomenon of converting excitation energy into Joule heat as a result of excitation of the SP of a metal by the excitation energy of a light-emitting molecule. The SP loss increases with a decrease in the distance between the light emission position and the electrode. Accordingly, the SP loss particularly appears in an organic EL element satisfying Expression 2 or any of 4 to 8′ as in an embodiment of the present invention.

The wave number of SP occurring at the interface between an optically infinitely thick metal layer and an organic compound layer generally has a relationship shown by Expression 9:

$${k}_{sp} = \sqrt{\frac{{ɛ}_{m} \cdot {ɛ}_{org}}{{ɛ}_{m} + {ɛ}_{org}}} {k}_{0} \approx \sqrt{\frac{{ɛ}_{m} \cdot {( {n}_{org} )}^{2}}{{ɛ}_{m} + {( {n}_{org} )}^{2}}} {k}_{0}$$

wherein, ∈ₘ represents the complex dielectric constant of a metal (anode), ∈_{org} is nearly equal to (n_{org})² and represents the complex dielectric constant of an organic compound layer, and k₀ represents the wave number of SP in the air. Here, for the sake of ease, the extinction coefficient of the organic compound layer is assumed to be 0. Incidentally, the complex refractive index can be measured with a commercially available spectroscopic ellipsometer employing well-known ellipsometry, which is a method of determining the optical constant of a material by observing a change in polarization when light is reflected on the surface of the material. Expression 9 shows that the wave number of SP decreases with refractive index dependence of the hole transport layer on a metal anode. The SP loss decreases with the wave number of SP.

The relationship between the refractive index and the light emission efficiency of a hole transport layer will be investigated based on simulation using an element composed of support substrate/Al (100 nm)/hole transport layer/electron-blocking layer (10 nm)/light-emitting layer (20 nm)/hole-blocking layer (10 nm)/electron transport layer (10 nm)/electron injection layer (10 nm)/Ag (24 nm). The light emission efficiencies of the element at refractive indices of the hole transport layer of 2.00, 1.85, 1.60, 1.40, and 1.20 are calculated. The numerical value shown in each parenthesis is the thicknesses of the layer. The hole transport layer has a thickness satisfying Expression 2. The maximum peak wavelength of the spectrum of light emitted from the light-emitting layer is 460 nm, which is almost or substantially equal to the maximum peak wavelength of the spectrum of light emitted from the organic EL element. The simulation is performed in accordance with the procedure described in Stefan Nowy et al., Light Extraction and Optical Loss Mechanisms in Organic Light-Emitting Diodes: Influence of the Emitter Quantum Efficiency, Journal of Applied Physics, volume 104, issue 12, article 123109, Dec. 15, 2008, American Institute of Physics, Melville, N.Y.

When the refractive indices of the hole transport layer are 2.00, 1.85, 1.60, 1.40, and 1.20, the light emission efficiencies at a chromaticity, CIEy, of 0.06 are 3.0 cd/A, 4.2 cd/A, 6.1 cd/A, 7.0 cd/A, and 7.8 cd/A, respectively. That is, there is a tendency that the light emission efficiency increases with a decrease in refractive index of the hole transport layer.

### Production of Light-Emitting Apparatus

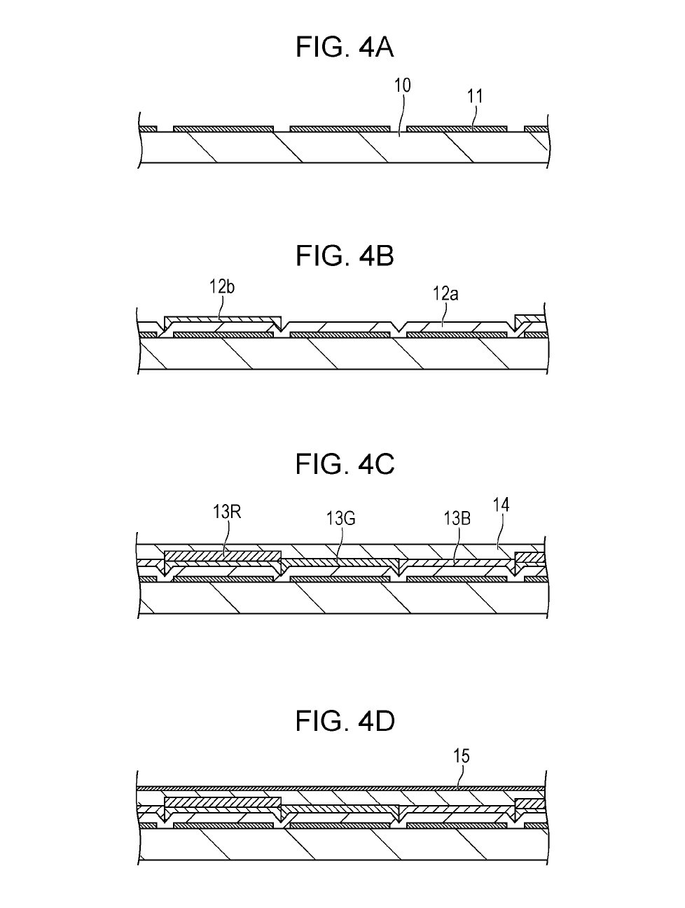

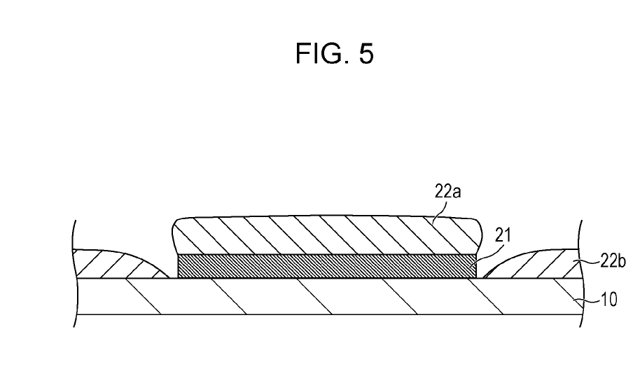

A process of producing a light-emitting apparatus according to the embodiment will be described with reference to FIGS. 4A to 4D. FIGS. 4A to 4D are cross-sectional schematic diagrams showing each step of the process of producing a light-emitting apparatus of the embodiment.

As shown in FIG. 4A, a plurality of first electrodes 11 are formed on a substrate 10. The first electrodes 11 are formed at positions corresponding to the respective pixels (organic EL elements). The first electrodes 11 are formed by a known method.

The first electrodes 11 are each formed by an electrically conductive metal material having high reflectance, such as Ag or Al, or an alloy of such metals. The first electrode 11 may have a monolayer or multi-layer structure. In particular, the first electrode 11 can have a laminated structure of a metal layer containing Al or Ag and a Mo metal layer from the viewpoint of hole injectability. The first electrode 11 has a thickness of 30 nm or more and 300 nm or less. In a first electrode 11 composed of a metal layer only, the reflecting surface of the first electrode 11 is the interface between the first electrode 11 and a hole transport layer 12a formed later. Alternatively, the first electrode 11 may have a laminated structure of a metal layer of the above-mentioned material and a transparent electrically conductive layer of a transparent electrically conductive material such as indium tin oxide (ITO). In such a case, the reflecting surface of the first electrode 11 is the interface between the metal layer and the transparent electrically conductive layer.

Examples of the substrate 10 include glass plates, plastic plates, these plates provided with thin-film transistors thereon, and silicon substrates provided with transistors thereon. The substrate 11 is a collective term indicating components formed prior to the formation of the first electrodes 11 and may have flexibility.

Subsequently, as shown in FIG. 4B, a hole transport layer 12a is formed by coating. Any known coating process can be employed, and, in particular, slit coating can form the hole transport layer 12a with a smaller variation in thickness. As a specific example, a process of forming the hole transport layer 12a by slit coating will be described below, but the hole transport layer 12a may be formed by any coating process such as spin coating.

The hole transport layer 12a can be formed by any known material. A material (solid component) for the hole transport layer 12a is mixed with a solvent such as toluene to prepare a coating solution. On this occasion, the proportion of the solid component to the solvent can be 1.0 wt % or less, in particular, 0.50 wt % or less. The side surfaces of the first electrode 11 also can be covered by using a coating solution having, for example, a viscosity of 0.5 to 1.0 cP.

The solution is applied onto the substrate 10 provided with the first electrodes 11 thereon to form a coating film. The application conditions may be appropriately set within the ranges of a slit interval of 10 μm or more and 100 μm or less, a distance between the slit head and the substrate 10 of 10 μm or more and 100 μm or less, and a head movement speed of 10 mm/s or more and 100 mm/s or less.

Subsequently, the substrate 10 provided with the coating film is annealed to evaporate the solvent to form a hole transport layer 12a.

Subsequently, a hole transport layer 12b is formed at the region corresponding to each red organic EL element for adjusting the optical distance of the red organic EL element. The hole transport layer 12b may be formed by coating or vapor deposition. The hole transport layer 12a and the hole transport layer 12b may be formed of the same material or different materials. These materials may be known materials.

The regions corresponding to the organic EL elements of other colors may be provided with hole transport layers as necessary. In such a case, the hole transport layers for organic EL elements of different colors may have different thicknesses or the same thickness and may be formed by the same material or different materials. Furthermore, a single transport layer may be common for organic EL elements of different colors.

Furthermore, another hole transport layer having an electron blocking property may be formed on the hole transport layers 12a, 12b. The hole transport layers 12a, 12b may have a multi-layer structure.

Subsequently, as shown in FIG. 4C, light-emitting layers 13R, 13G, 13B are formed on the hole transport layers 12a, 12b at the positions corresponding to the respective organic EL elements. Furthermore, an electron transport layer 14 is formed on the light-emitting layers 13R, 13G, 13B.

The light emission position of each light-emitting layer 13R, 13G, 13B refers to a region showing the maximum light emission intensity in the light-emitting layer. When the light-emitting layer 13R, 13G, 13B contains a host material and a light emission dopant material, the light emission position is determined based on the relationship between the highest occupied molecular orbital (HOMO) level energies and the lowest unoccupied molecular orbital (LUMO) level energies of the host material and the light emission dopant material.

In the case of satisfying Expression 10, the light emission position of the light-emitting layer 13R, 13G, 13B is present on the hole transport layer 12a, 12b side than the center of the light-emitting layer 13R, 13G, 13B. More specifically, the light emission position is present near the interface between the light-emitting layer 13R, 13G, 13B and the hole transport layer 12a, 12b (within 10 nm from the interface between the light-emitting layer 13R, 13G, 13B and the hole transport layer 12a, 12b). When the HOMO level energy H_{H} and the LUMO level energy L_{H} of the host material of the light-emitting layer 13R, 13G, 13B and the HOMO level energy H_{D} and the LUMO level energy L_{D} of the light emission dopant material satisfy Expression 10:

|H_{D}|<|H_{H}| and |H_{H}|−|H_{D}|>|L_{D}|−|L_{H}|,

holes are readily trapped by the light emission dopant material to reduce the mobility of the holes. It is therefore believed that the probability of recombination of electrons and holes is increased on the hole transport layer 12a, 12b side to increase the light emission intensity on the hole transport layer 12a, 12b side.

In the case of satisfying Expression 11, the light emission position of the light-emitting layer 13R, 13G, 13B is present on the electron transport layer 14 side than the center of the light-emitting layer 13R, 13G, 13B. More specifically, the light emission position is present near the interface between the light-emitting layer 13R, 13G, 13B and the electron transport layer 14 (within 5 nm from the interface between the light-emitting layer 13R, 13G, 13B and the electron transport layer 14). In the light-emitting layer satisfying Expression 11:

|L_{D}|>|L_{H}| and |L_{D}|−|L_{H}|>|H_{H}|−|H_{D}|,

electrons are readily trapped by the light emission dopant material to reduce the mobility of the electrons. It is therefore believed that the probability of recombination of electrons and holes is increased on the electron transport layer 14 side to increase the light emission intensity on the electron transport layer 14 side.

The light-emitting layers 13R, 13G, 13B and the electron transport layer 14 are formed by known methods using known materials. The light-emitting layers 13R, 13G, 13B can be formed by vapor deposition showing rectilinearity not to extend to other pixel regions and thereby to avoid mixing of colors. Specifically, for example, the light-emitting layers 13R, 13G, 13B can be formed by vapor deposition under a pressure of 1.0×10⁻⁵ Pa or more and 1.0×10⁻³ Pa or less.

The electron transport layer 14 may have a multi-layer structure. Furthermore, the electron transport layer 14 may be composed of two layers in only a part of the pixels. The electron transport layer 14 may have a hole-blocking property. In particular, in the electron transport layer 14 having a multi-layer structure, the electron transport layer on the light-emitting layer 13R, 13G, 13B side may have a hole-blocking property. Furthermore, the electron transport layer 14 may contain an alkali metal, an alkaline earth metal, or a compound thereof for enhancing the electron injection property.

Subsequently, as shown in FIG. 4D, a second electrode 15 is formed on the electron transport layer 14.

The second electrode 15 can be formed by an electrically conductive metal material having an excellent electron injection property, such as Ag, AgMg, or AgCs, or a transparent electrically conductive material such as ITO. The second electrode 15 of a metal material has a thickness of 2 nm or more and 30 nm or less, whereas the second electrode 15 of a transparent electrically conductive material has a thickness of 50 nm or more and 200 nm or less. The second electrode 15 may have a laminated structure of a metal material and a transparent electrically conductive material.

Furthermore, an optical adjustment layer of an organic or inorganic material may be disposed on the second electrode 15. The light emission efficiency can be increased through an increase in optical interference effect by adjusting the thickness of the optical adjustment layer.

The reflecting surface of the second electrode 15 having a metal layer is the interface of the metal layer on the organic compound layer (light-emitting layer) side, whereas the reflecting surface of the second electrode 15 composed of only an electrically conductive oxide layer is the interface of the electrically conductive oxide layer on the opposite side of the organic compound layer (light-emitting layer).

The organic EL element may be sealed with sealing glass or may be sealed with a sealing film of an inorganic material disposed on the second electrode 15. The sealing film is a monolayer or multilayer of an inorganic material such as silicon nitride, silicon oxide, silicon oxynitride, or aluminum oxide. The sealing layer has a thickness of 100 nm or more and 10 μm or less.

The light-emitting apparatus of an embodiment of the present invention can be applied to an image-forming apparatus such as a laser beam printer, more specifically, an image-forming apparatus including a photosensitive member on which a latent image is formed by a light-emitting apparatus and charging means for charging the photosensitive member.

The light-emitting apparatuses have been described above. An embodiment of the present invention can also be applied to a display apparatus having a plurality of organic EL elements. In such a case, the display apparatus may include a plurality of organic EL elements emitting light having different colors or may include a plurality of organic EL elements emitting light having a single color. The display apparatus can be used as the display or electronic viewfinder of an image pickup apparatus such as a digital camera or digital video camera having image pickup elements such as CMOS sensors. In addition, the display apparatus can be used as the display of an image-forming apparatus or the display of a personal digital assistant such as a cellular phone or smartphone. Furthermore, the display apparatus may have a configuration including a plurality of organic EL elements emitting light having a single color and red, green, and blue color filters.

### EXAMPLES

Examples of an embodiment of the present invention will now be described with reference to FIGS. 4A to 4D. The materials and the element configurations in the Examples are preferred examples, and an embodiment of the present invention is not limited thereto.

### Example 1

As shown in FIG. 4A, first electrodes (anodes) 11 having an Al/Mo laminated structure were formed on a substrate 10 formed by forming thin-film transistors (TFTs) and an organic planarizing layer on a glass plate. The Al layer had a thickness of 45 nm, and the Mo layer had a thickness of 5 nm. The substrate 10 provided with the first electrodes 11 was washed with pure water and was subjected to baking treatment in a vacuum atmosphere and then to pretreatment with oxygen plasma.

Subsequently, as shown in FIG. 4B, a film having a thickness of 27 nm of Compound 1 was formed as a hole transport layer 12a. Specifically, slit coating was performed using a toluene solution containing 0.5 wt % of Compound 1 under conditions of a slit interval of 50 μm, a distance between the slit head and the substrate 10 of 50 μm, and a head movement speed of 60 mm/s. After coating, the substrate 10 was heated at 80° C. for 10 minutes in a vacuum oven to anneal the coating film to give a hole transport layer 12a.

Subsequently, a hole transport layer 12b having a thickness of 45 nm was formed by vapor deposition of Compound 2 on the hole transport layer 12a at the portions for red pixels using a metal mask having a pixel-like shape. The vapor deposition was performed under a pressure of 1.0×10⁻⁴ Pa and a film formation speed of 1.00 Å/s.

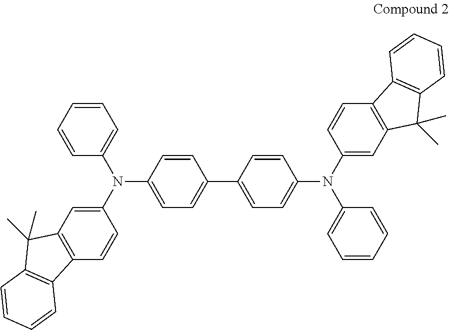 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Subsequently, as shown in FIG. 4C, Compound 3 as the host material, Compound 4 (volume proportion: 4%) as the light emission dopant, and Compound 2 (volume proportion: 15%) as the assist dopant were codeposited on the hole transport layer 12b using a metal mask having a pixel shape to form red light-emitting layers 13R having a thickness of 25 nm. The conditions for vapor deposition were the same as those for the formation of the hole transport layer 12b. Compounds 3 and 4 contained in the red light-emitting layer 13R satisfy Expression 10, and therefore the light emission position was present on the hole transport layer 12b side.

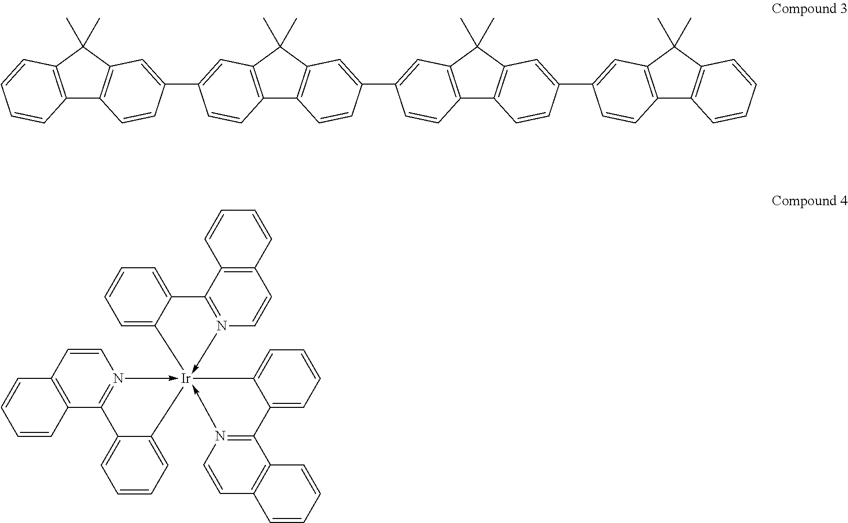

Subsequently, green light-emitting layers 13G were formed by vapor deposition on the hole transport layer 12a at the portions for green pixels using a metal mask having a pixel-like shape. Specifically, Compound 5 as the host material, Compound 6 (volume proportion: 1.5%) as the light emission dopant, and Compound 7 (volume proportion: 60%) were codeposited in a thickness of 35 nm. The conditions for vapor deposition were the same as those for the formation of the hole transport layer 12b. Compounds 5 and 6 contained in the green light-emitting layer 13G satisfy Expression 10, and therefore the light emission position was present on the electron transport layer 14 side.

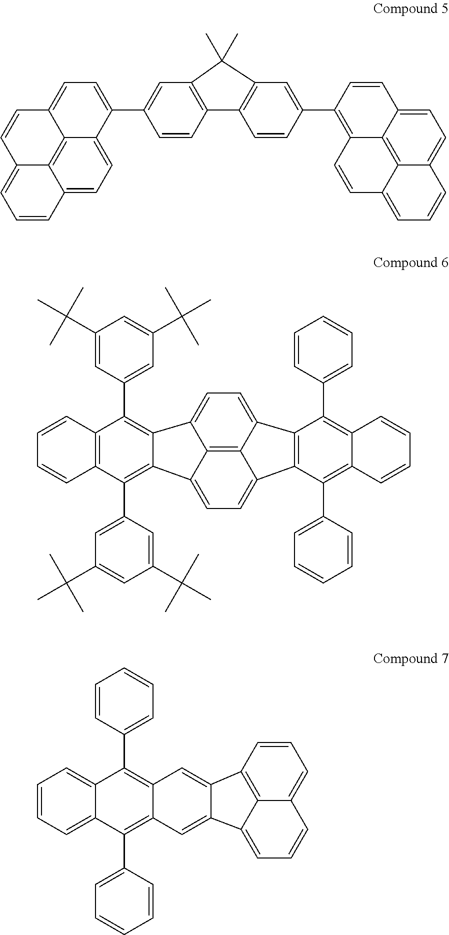

Subsequently, Compound 8 as the host material and Compound 9 (volume proportion: 0.5%) as the light emission dopant were codeposited on the hole transport layer 12a at the portions for blue pixels using a metal mask having a pixel-like shape to form blue light emitting layers 13B having a thickness of 20 nm. The conditions for vapor deposition were the same as those for the formation of the hole transport layer 12b. Compounds 8 and 9 contained in the blue light-emitting layer 13B satisfy Expression 11, and therefore the light emission position was present on the electron transport layer 14 side.

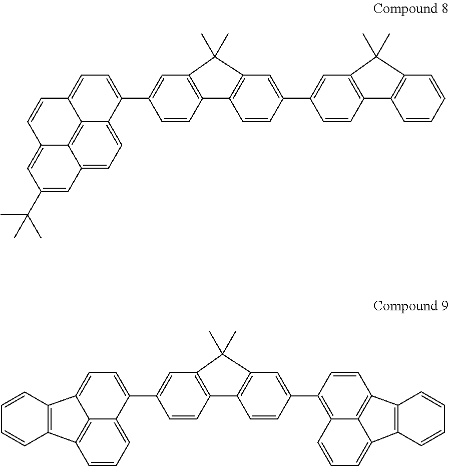

Subsequently, a phenanthroline derivative represented by Compound 10 was deposited over all the light-emitting layers 13R, 13G, 13B to form an electron transport layer 14 having a thickness of 40 nm. The conditions for vapor deposition were the same as those for the formation of the hole transport layer 12b.

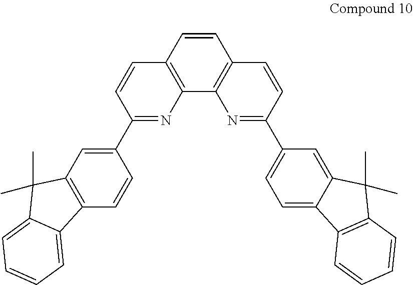

Subsequently, as shown in FIG. 4D, cesium carbonate (volume proportion: 3%) and Ag were codeposited on the electron transport layer 14 in a thickness of 6 nm, and Ag was further deposited in a thickness of 20 nm to form a second electrode 15.

The substrate was transferred to a glovebox and was sealed with a glass cap containing a desiccant under a nitrogen atmosphere.

The results of evaluation of the light-emitting elements prepared by the above-described procedures show that the maximum peak wavelengths of spectra of light emitted from the red, green, and blue organic EL elements were λ_{R}=623 nm, λ_{G}=517 nm, and λ_{B}=452 nm, respectively.

In the blue organic EL element produced by the above-described procedure, the refractive indices at the wavelength λ_{B} of the hole transport layer 12a and the light-emitting layer 13B were respectively 1.88 and 1.80, and the first optical distance calculated was (27 nm×1.88)+(20 nm×1.80)=86.8 nm.

The phase shift Φ₁ calculated from the refractive index on the first electrode 11 side and the absorption coefficient was −139°. Therefore, the first optical distance calculated from Expression 2 at λ_{B}=452 nm is 87.3 nm, which is substantially agrees with the actual first optical distance of the produced organic EL element. The refractive index and the absorption coefficient were measured using a film of each material with a spectroscopic ellipsometer.

Table 1 collectively shows the first optical distance and the second optical distance of the organic EL element of each color produced in Example 1 and the optical distances calculated from Expressions 2 and 6. The optical distances of the red, green, and blue organic EL elements having the structure of Example 1 substantially agreed with the values calculated from Expression 2. The structure of Example 1 satisfied Expression 4, 5, 4′, 5′, 7, 8, 7′, and 8′.

TABLE 1

| | | Red | Green | Blue |
|---|---|---|---|---|
| First optical | Example 1 | 132 | 102 | 87 |
| distance (nm) | Calculation from | 131 | 103 | 87 |
| | Expression 2 | | | |
| Second optical | Example 1 | 117 | 85 | 72 |
| distance (nm) | Calculation from | 112 | 86 | 70 |
| | Expression 6 | | | |

### Example 2

Each organic EL element was produced as in Example 1 except that the hole transport layer 12a in Example 2 was formed by spin coating of a toluene solution containing 0.5 wt % of Compound 1. The spin coating was performed at 850 rpm.

### Comparative Example 1

Each organic EL element was produced as in Example 1 except that the hole transport layer 12a in Comparative Example 1 was formed by vapor deposition of Compound 1. The vapor deposition was performed at a pressure of 1.0×10⁻⁴ Pa and a film formation speed of 1.00 Å/s.

Evaluation of organic EL element The organic EL elements produced in each Example and Comparative Example were evaluated for lighting. The lighting was evaluated by uniformly lighting the entire elements at an applied voltage of 3 V, counting the number of unlighted pixels, and calculating the ratio of the number of unlighted pixels to the number of the entire pixels. The ratios in Example 1, Example 2, and Comparative Example 1 were 0.10 ppm, 0.25 ppm, and 1.00 ppm, respectively. The value of 0.25 ppm means that the number of unlighted pixels is less than one in a light-emitting apparatus and that the quality of the light-emitting apparatus is good. The results demonstrate that the yield of the hole transport layers 12a formed by coating is higher than that of the hole transport layers 12a formed by vapor deposition.

The light emission efficiencies of the red, green, and blue organic EL elements of Example 1 and Comparative Example 1 were measured. The results demonstrate that though there were almost no differences in the light emission efficiencies of the red and green organic EL elements between Example 1 and Comparative Example 1, the light emission efficiency of the blue organic EL element of Example 1 was 5.5 cd/A, which is higher 1.2 times than that, 4.6 cd/s, of the organic EL element of Comparative Example 1. It is believed that this is caused by a reduction in SP loss due to a reduced refractive index of the hole transport layer 12a.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-018815 filed Jan. 31, 2012, which is hereby incorporated by reference herein in its entirety.

What is claimed is:

1. A light-emitting apparatus comprising:
a substrate; and
a plurality of organic EL elements on the substrate, the organic EL elements each comprising a first electrode, a second electrode, a light-emitting layer, and a charge transport layer between the first electrode and the light-emitting layer, the first electrode being disposed for each organic EL element, and light emitted from the light-emitting layer being extracted from the second electrode, wherein
the charge transport layer is formed by coating; and
the first optical distance L₁ between the light emission position of the light-emitting layer and the reflecting surface of the first electrode of each organic EL element satisfies Expression A:
L₁>0 and (λ/8)×(−1−2Φ₁/π)<L₁<(λ/8)×(1−2Φ₁/π)
wherein, λ represents the maximum peak wavelength of the spectrum of light emitted by each organic EL element, and Φ₁ represents the phase shift of the reflecting surface of the first electrode at the wavelength λ.

2. The light-emitting apparatus according to claim 1, wherein the charge transport layer is formed by coating so as to be in contact with the top surface and the side surfaces of the first electrode.

3. The light-emitting apparatus according to claim 1, wherein the first optical distance L₁ satisfies Expression B:
(λ/16)×(−1−4Φ₁/π)≦L₁≦(λ/16)×(1−4Φ₁/π).

4. The light-emitting apparatus according to claim 1, wherein the first optical distance L₁ satisfies Expression C:
λ/8<L₁<3λ/8.

5. The light-emitting apparatus according to claim 1, wherein the first optical distance L₁ satisfies Expression D:
3λ/16≦L₁≦5λ/16.

6. The light-emitting apparatus according to claim 1, wherein the second optical distance L₂ between the light emission position of the light-emitting layer and the reflecting surface of the second electrode of each organic EL element satisfies Expression E:
L₂>0 and (λ/8)×(−1−2Φ₂/π)<L₂<(λ/8)×(1−2Φ₂/π)
wherein Φ₂ represents the phase shift of the second electrode at the wavelength λ.

7. The light-emitting apparatus according to claim 1, wherein the second optical distance L₂ between the light emission position of the light-emitting layer and the reflecting surface of the second electrode of each organic EL element satisfies Expression F:
(λ/16)×(−1−4Φ₂/π)≦L₂≦(λ/16)×(1−4Φ₂/π)
wherein Φ₂ represents the phase shift of the second electrode at the wavelength λ.

8. The light-emitting apparatus according to claim 1, wherein the second optical distance L₂ between the light emission position of the light-emitting layer and the reflecting surface of the second electrode of each organic EL element satisfies Expression G:
λ/8<L₂<3λ/8.

9. The light-emitting apparatus according to claim 1, wherein the second optical distance L₂ between the light emission position of the light-emitting layer and the reflecting surface of the second electrode of each organic EL element satisfies Expression H:
3λ/16≦L₂≦5λ/16.

10. The light-emitting apparatus according to claim 1, wherein the charge transport layer is formed by slit coating.

11. An image-forming apparatus comprising the light-emitting apparatus according to claim 1, a photosensitive member on which a latent image is formed by the light-emitting apparatus, and a charging unit for charging the photosensitive member.

12. A display apparatus comprising:
a substrate; and
a plurality of organic EL elements on the substrate, the organic EL elements each comprising a first electrode, a second electrode, a light-emitting layer, and a charge transport layer between the first electrode and the light-emitting layer, the first electrode being disposed for each organic EL element, and light emitted from the light-emitting layer being extracted from the second electrode, wherein
the charge transport layer is formed by coating; and
the first optical distance L₁ between the light emission position of the light-emitting layer and the reflecting surface of the first electrode of each organic EL element satisfies Expression I:
L₁>0 and (λ/8)×(−1−2Φ₁/π)<L₁<(λ/8)×(1−2Φ₁/π)
wherein, λ represents the maximum peak wavelength of the spectrum of light emitted by each organic EL element, and Φ₁ represents the phase shift of the reflecting surface of the first electrode at the wavelength λ.

13. The display apparatus according to claim 12, wherein the charge transport layer is formed by coating so as to be in contact with the top surface and the side surfaces of the first electrode.

14. The display apparatus according to claim 12, wherein the plurality of organic EL elements include a plurality of organic EL elements emitting light having different colors.

15. An image pickup apparatus comprising the display apparatus according to claim 12 and an image pickup element.

16. A method of producing a light-emitting apparatus comprising a substrate and a plurality of organic EL elements on the substrate, the organic EL elements each comprising a first electrode, a second electrode, a light-emitting layer, and a charge transport layer between the first electrode and the light-emitting layer, the first electrode being disposed for each organic EL element, and light emitted from the light-emitting layer being extracted from the second electrode, the method comprising:
forming a first electrode on a substrate;
forming a charge transport layer on the first electrode by coating;
forming a light-emitting layer on the charge transport layer; and
forming a second electrode on the light-emitting layer, wherein
the first optical distance L₁ between the light emission position of the light-emitting layer and the reflecting surface of the first electrode of each organic EL element satisfies Expression J:
L₁>0 and (λ/8)×(−1−2Φ₁/π)<L₁<(λ/8)×(1−2Φ₁/π)
wherein, λ represents the maximum peak wavelength of the spectrum of light emitted by each organic EL element, and Φ₁ represents the phase shift of the reflecting surface of the first electrode at the wavelength λ.

17. The method of producing a light-emitting apparatus according to claim 16, wherein the charge transport layer is formed by coating so as to be in contact with the top surface and the side surfaces of the first electrode.

18. The method of producing a light-emitting apparatus according to claim 16, wherein the charge transport layer is formed by slit coating.
